(19) United States
(12) Patent Application Publication
(10) Pub. No.: US 2014/0103354 A1
(43) Pub. Date: Apr. 17, 2014

(54) NITRIDE SEMICONDUCTOR STRUCTURE

(71) Applicant: Industrial Technology Research Institute, Hsinchu (TW)

(72) Inventors: Chih-Wei Hu, Taoyuan County (TW); Chen-Zi Liao, Nantou County (TW); Yen-Hsiang Fang, New Taipei City (TW); Rong Xuan, New Taipei City (TW)

(73) Assignee: Industrial Technology Research Institute, Hsinchu (TW)

(21) Appl. No.: 14/049,209

(22) Filed: Oct. 9, 2013

(30) Foreign Application Priority Data
Oct. 12, 2012 (TW) 101137770

(51) Int. Cl. H01L 29/205

(52) U.S. Cl. CPC H01L 29/205
USPC 257/76

(57) ABSTRACT

A nitride semiconductor structure including a silicon substrate, a nucleation layer, a buffer layer and a nitride semiconductor layer is provided. The nucleation layer disposed on the silicon substrate includes a cubic silicon carbon nitride (SiCN) layer. The buffer layer is disposed on the nucleation layer. The nitride semiconductor layer is disposed on the buffer layer.

### CROSS-REFERENCE TO RELATED APPLICATION

This application claims the priority benefit of Taiwan application serial no. 101137770, filed on Oct. 12, 2012. The entirety of the above-mentioned patent application is hereby incorporated by reference herein and made a part of this specification.

### TECHNICAL FIELD

The disclosure relates to a nitride semiconductor structure, and more particularly, to a nitride semiconductor structure that uses a silicon substrate.

### BACKGROUND

Currently, the fabrication cost of nitride light-emitting diodes is much higher than other illuminating devices, and sapphire substrates for growth of nitride have shortcomings such as poor thermal conductivity which seriously affects the lifespan of the nitride light-emitting diodes. Therefore, replacing the current sapphire substrate with a lower-cost and high thermal conductive substrate is suggested. Due to the several advantages of silicon substrates such as high thermal conductivity, high electrical conductivity, ability to be cut easily and low cost, light-emitting diode fabricated over a silicon substrate is developed in recent years.

However, production yield rate of large-sized nitride semiconductor structures fabricated over silicon substrates is low, it is difficult to significantly lower the cost of the devices accordingly. The main factor for affecting the yield rate of large-sized nitride semiconductor structures is thermal expansion mismatch and lattice mismatch between the nitride semiconductor layer and the silicon substrate. Thermal expansion mismatch and lattice mismatch between the nitride semiconductor layer and the silicon substrate cause difficulty in stress release and increase defect density. Accordingly the nitride semiconductor structures may crack easily. Moreover, the chip bonding equipment and the laser lift-off equipment are expensive, and the yield rate of the chip bonding process and the laser lift-off process is low.

### SUMMARY

The disclosure provides a nitride semiconductor structure which can reduce the stress caused by thermal expansion mismatch and lattice mismatch between the nitride semiconductor layer and the silicon substrate, thus reducing probability of cracks. Moreover, tedious processes such as chip bonding and laser ablation are not needed, which effectively improves the yield rate of large-sized nitride semiconductor structures with no cracks.

The disclosure provides a nitride semiconductor structure including a silicon substrate, a nucleation layer, a buffer layer and a nitride semiconductor layer. The nucleation layer is disposed on the silicon substrate, and the nucleation layer includes a cubic silicon carbon nitride (SiCN) layer or a graded layer comprising silicon carbide and silicon carbon nitride. The buffer layer is disposed on the nucleation layer. The nitride semiconductor layer is disposed on the buffer layer.

Based on the above, a cubic silicon carbon nitride layer or a graded layer comprising silicon carbide and silicon carbon nitride is used as a nucleation layer on the nitride semiconductor structure of the disclosure to effectively reduce the stress between the nitride semiconductor layer and the silicon substrate caused by the thermal expansion mismatch (i.e. different in coefficient of thermal expansion). Moreover, the nitride semiconductor structure of the disclosure can avoid tedious processes such as chip bonding and laser ablation, which improves the yield rate of large nitride semiconductor structures.

In order to make the aforementioned features and advantages of the disclosure more comprehensible, embodiments accompanied with figures are described in detail below.

### BRIEF DESCRIPTION OF THE DRAWINGS

FIG. 1A is a schematic diagram of a nitride semiconductor structure according to one embodiment of the disclosure.

FIG. 1B is a schematic diagram of a nitride semiconductor structure according to another embodiment of the disclosure.

FIG. 2 schematically illustrates that a silicon carbon nitride (SixCyNz) layer applied to a patterned silicon substrate.

FIG. 3 is a scanning electron microscope (SEM) cross-sectional image of the nitride semiconductor structure of FIG. 1B.

FIG. 4A schematically illustrates the definition of depth of the silicon carbon nitride layer 122 of the nitride semiconductor structure as shown in FIG. 1A.

FIG. 4B schematically illustrates the relationship between depth of the silicon carbon nitride layer and atomic percentage when the silicon carbon nitride layer is analyzed.

FIG. 5 schematically illustrates the relationship between peak position and intensity when the nitride semiconductor structure of FIG. 1A is analyzed.

FIG. 6 is a schematic diagram of a nitride semiconductor structure according to another embodiment of the disclosure.

### DETAILED DESCRIPTION OF DISCLOSED EMBODIMENTS

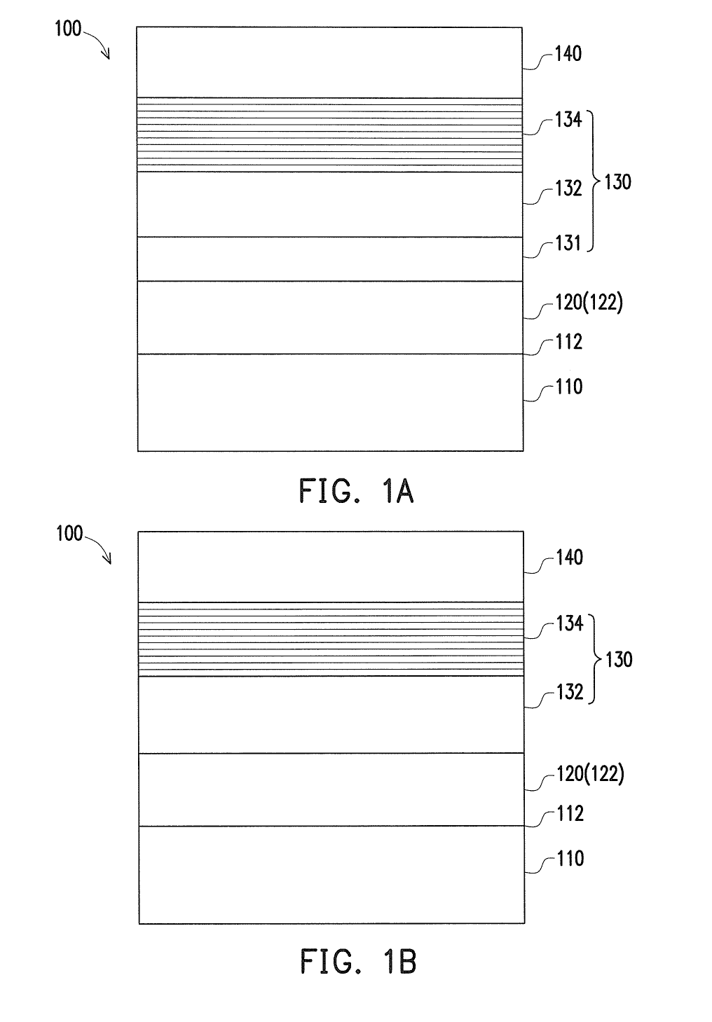

FIG. 1A is a schematic diagram of a nitride semiconductor structure according to one embodiment of the disclosure. Referring to FIG. 1A, a nitride semiconductor structure 100 in the present embodiment includes a silicon substrate 110, a nucleation layer 120, a buffer layer 130 and a nitride semiconductor layer 140. The nucleation layer 120 is disposed on the silicon substrate 110, and in the present embodiment, the nucleation layer 120 includes a cubic silicon carbon nitride (SixCyNz) layer 122. The buffer layer 130 is disposed on the nucleation layer 120, and in the present embodiment, an upper surface of the cubic silicon carbon nitride layer 122 is in contact with hexagonal nitrides. The nitride semiconductor layer 140 is disposed on the buffer layer 130. In the present embodiment, the nucleation layer 120, the buffer layer 130 and the nitride semiconductor layer 140 are deposited respectively on the silicon substrate 110 by metal organic chemical vapor disposition (MOCVD). However, the fabricating methods of the nucleation layer 120, the buffer layer 130 and the nitride semiconductor layer 140 formed on the silicon substrate 110 are not limited to metal organic chemical vapor disposition (MOCVD).

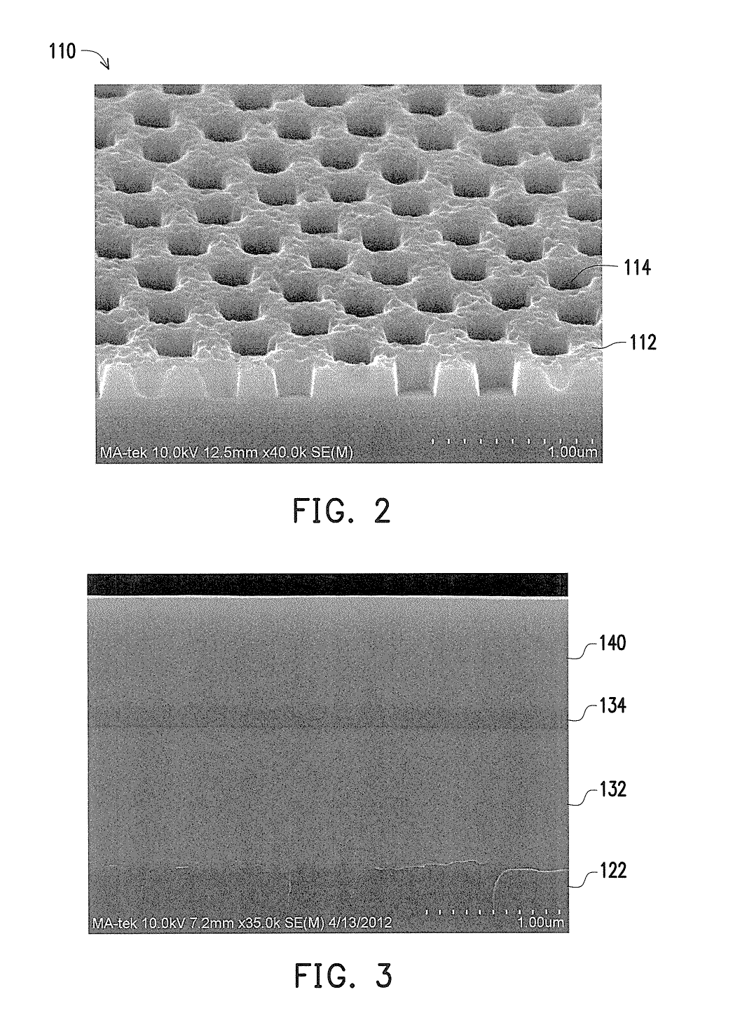

FIG. 2 schematically illustrates that a silicon carbon nitride (SixCyNz) layer applied to a patterned silicon substrate. Referring to FIG. 2, the silicon substrate 110 includes a surface 112 in contact with the nucleation layer 120 and a plurality of cavities 114, where the cavities 114 are concave on the surface 112, so that the nucleation layer 120 formed on the silicon substrate 110 may grow laterally over the cavities. In other words, the silicon carbon nitride (SixCyNz) layer is applied to a patterned silicon substrate for epitaxial growth. When the nitride semiconductor structure 100 is used to fabricate light-emitting diode devices, a plurality of voids formed between the nucleation layer 120 and the silicon substrate 110 within the cavities 114 and the voids is helpful to release stress and scattered the light emitted from the light emitting layers of light-emitting diode devices. Therefore, light extraction efficiency of light-emitting diode devices may be enhanced. Moreover, in the present embodiment, the crystal orientation (i.e. Miller index) of the silicon substrate 110 is (1 1 1). In FIG. 2, the silicon substrate 110 having the cavities 114 thereon is merely described for illustration. In other embodiments, the surface 112 of the silicon substrate 110 may be a flat surface. The types of the silicon substrate 110 are not limited in the present disclosure.

In the silicon carbon nitride (SixCyNz) layer 122, the parameters x, y and z satisfy the equation: x+y+z=1, where z is less than 0.3. The nitride semiconductor structure 100 in the present embodiment effectively reduces the stress between the nitride semiconductor layer 140 and the silicon substrate 110 caused by the thermal expansion mismatch (CTE mismatch) and lattice mismatch when the parameters x, y and z satisfy the above-mentioned conditions.

The buffer layer 130 includes a hexagonal first nitride layer 131 and a second nitride layer 132, wherein the hexagonal first nitride layer 131 is in contact with the nucleation layer 120. In the present embodiment, the first nitride layer 131 includes an hexagonal aluminum nitride (AlN) layer. The second nitride layer 132 is aluminum contained nitride layer, for example. In the present embodiment, the second nitride layer 132 is a graded AlGaN layer with step graded aluminum content, and the probability of pits or cracks occurring in the nitride semiconductor structure 100 of the present embodiment can be reduced because the stress between the nitride semiconductor layer 140 and the silicon substrate 110 resulted from the thermal expansion mismatch can be lowered by the graded AlGaN layer with step graded aluminum content. In other embodiments, the second nitride layer 132 may also include a graded AlGaN layer with continuously graded aluminum content, wherein the graded AlGaN layer with continuously graded aluminum content may also reduce the stress between the nitride semiconductor layer 140 and the silicon substrate 110 resulted from the thermal expansion mismatch.

In the present embodiment, the buffer layer 130 further includes a composite layer 134, wherein the composite layer 134 includes a plurality of stacked silicon carbide layers and third nitride layers or a plurality of stacked silicon carbon nitride layers and third nitride layers. In the present embodiment, the silicon carbon nitride layer of the composite layer 134 is a cubic silicon carbon nitride layer. The composite layer 134 is disposed between the second nitride layer 132 and the nitride semiconductor layer 140. In the present embodiment, the third nitride layers are, for example. gallium nitride (GaN) layers. The composite layer 134 in the present embodiment is, for instance, a superlattice structure formed by a plurality of silicon carbon nitride layers and GaN layers stacked alternately, so as to reduce the stress between the nitride semiconductor layer 140 and the silicon substrate 110 resulted from the thermal expansion mismatch. Moreover, in the present embodiment, the nitride semiconductor layer 140 includes a GaN layer.

As shown in FIG. 1A, in the present embodiment, the buffer layer 130 may include the first nitride layer 131 (e.g. an AlN layer), the second nitride layer 132 (e.g. a graded AlGaN layer with step graded aluminum content) and the composite layer 134 (e.g. a superlattice structure formed by a plurality of silicon carbon nitride layers and GaN layers).

FIG. 1B is a schematic diagram of a nitride semiconductor structure according to another embodiment of the disclosure. Referring to FIG. 1B, an another embodiment, the first nitride layer may be a part of the second nitride layer 132. That is to say, the buffer layer 130 may include the second nitride layer 132 (e.g. a graded AlGaN layer with step graded aluminum content) and the composite layer 134 (e.g. a superlattice structure formed by a plurality of silicon carbon nitride layers and GaN layers), and the second nitride layer 132 is a graded AlN/AlGaN layer with graded aluminum content or a graded AlN/AlGaN/GaN layer with graded aluminum content.

FIG. 3 is a scanning electron microscope (SEM) cross-sectional image of the nitride semiconductor structure of FIG. 1B. Referring to FIG. 3, in the cross-section view, there is almost no crack occurred in the nitride semiconductor structure 100 of the present embodiment. That is to say, the silicon carbon nitride layer 122 formed in the nitride semiconductor structure 100 may greatly reduce the stress between the nitride semiconductor layer 140 and the silicon substrate 110 resulted from the thermal expansion mismatch and lattice mismatch, thus effectively improving the epitaxial quality of the nitride semiconductor structure 100.

In the present embodiment, the nucleation layer 120, the buffer layer 130 and the nitride semiconductor layer 140 of the nitride semiconductor structure 100 may have certain thicknesses, respectively. The thickness of the silicon carbon nitride layer 122 is about 50 nanometers to about 5000 nanometers. The thickness of the first nitride layer 131 (e.g. the AlN layer) is about 50 nanometers to about 500 nanometers. The thickness of the second nitride layer 132 (e.g. the graded AlGaN layer) is about 0.5 micrometers to about 10 micrometers. The superlattice structure of the composite layer 134 may include 4 pairs to 120 pairs of silicon carbon nitride layers and GaN layers and has a thickness of about 50 nanometers to about 300 nanometers. If the nitride semiconductor layer 140 is a GaN layer, for example, the thickness of the GaN layer is about 0.5 micrometers to about 10 micrometers. Preferably, the thickness of the GaN layer is greater than 1 micrometer. Therefore, the overall thickness of the nitride semiconductor structure 100 may be increased.

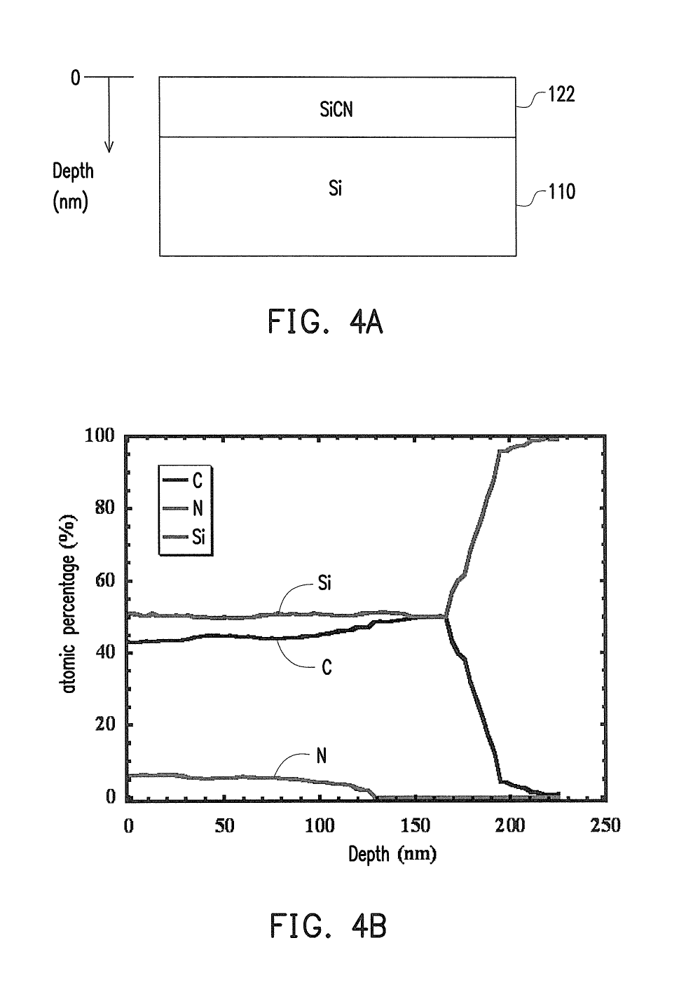

When the nitride semiconductor structure 100 is analyzed from the top surface of the silicon carbon nitride layer 122 towards the silicon substrate 110 along the depth direction, the atomic percentage of nitrogen atoms is less than about 30%. In one of the embodiments, the atomic percentage of nitrogen atoms is less than about 15%. In another embodiment, the atomic percentage of nitrogen atoms is less than about 10%. FIG. 4A schematically illustrates the definition of depth of the silicon carbon nitride layer 122 of the nitride semiconductor structure 100 shown in FIG. 1A. FIG. 4B schematically illustrates the relationship between depth of the silicon carbon nitride layer and atomic percentage when the silicon carbon nitride layer is analyzed. Referring to FIG. 4A and FIG. 4B, when the atomic percentage of each cross-section is analyzed starting from the top surface of the silicon carbon nitride layer 122 towards the silicon substrate 110 along the depth direction, as shown in FIG. 4B, the atomic percentage of nitrogen atoms is about 6% when the depth is between 0 nano meter and 100 nanometers, and the atomic percentage of nitrogen atoms gradually decreases when the depth is between 100 nanometers and 130 nanometers. As shown in FIG. 4B, the atomic percentage of nitrogen atoms in the silicon carbon nitride layer 122 gradually decreases from the top surface of the silicon carbon nitride layer 122 towards the silicon substrate 110 along the depth direction. In the present embodiment, the silicon carbon nitride layer 122 is a graded layer with graded nitrogen content. Moreover, because the nucleation layer 120 (i.e. the silicon carbon nitride layer 122) may be replaced by a graded layer comprising silicon carbide and silicon carbon nitride, the atomic percentage of nitrogen atoms in the graded layer comprising silicon carbide and silicon carbon nitride also gradually decreases from the top surface of the silicon carbon nitride layer 122 towards the silicon substrate 110 along the depth direction.

In the section between the depths of 0 nanometer and 165 nanometers, the atomic percentage of carbon atoms increases slowly from 43% to close to 50%, and in the section at the depth of greater than 165 nanometers, the atomic percentage of carbon atoms decreases drastically. In the section between the depths of 0 nanometer and 165 nanometers, the atomic percentage of silicon atoms is about 50%, and in the section at the depth of greater than 165 nanometers, the atomic percentage of silicon atoms increases drastically. As shown in FIG. 4B, carbon atoms are substituted by nitrogen atoms in the section between the depths of 0 nanometer and 130 nanometers. In the section between the depths of 0 nanometer and 100 nanometers, the amount of carbon atoms substituted by nitrogen atoms is about 6% of the atomic percentage. And in the section between the depths of 100 nanometers and 130 nanometers, the atomic percentage of carbon atoms substituted by nitrogen atoms gradually decreases.

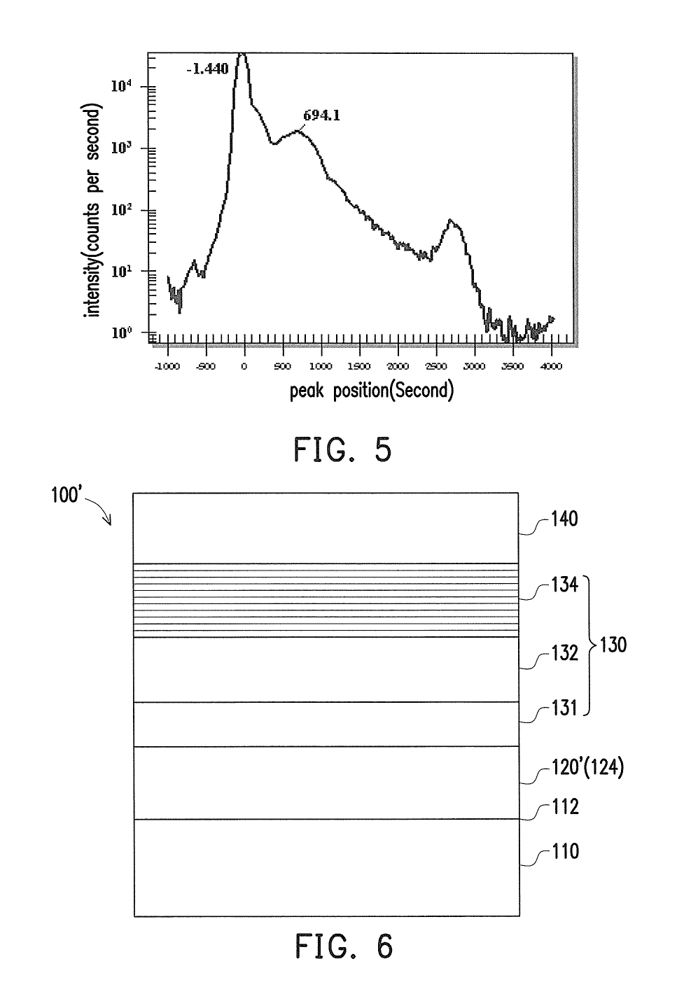

FIG. 5 schematically illustrates the relationship between peak position and intensity when the nitride semiconductor structure of FIG. 1A is analyzed. Referring to FIG. 5, in the relationship between peak position and intensity, a peak with a peak position of −1.440 seconds represents GaN is detected, and a peak with a peak position between 2500 and 3000 seconds represents silicon carbon nitride is detected.

As shown in FIG. 3 to FIG. 5, during the actual testing, the existence of nitrogen atoms at the position of the nucleation layer 120 may be detected in the nitride semiconductor structure 100 in the present embodiment. Silicon carbon nitride can be analyzed by the relationship between peak position and intensity. Moreover, the scanning electron microscope (SEM) cross-sectional image shows that the nitride semiconductor structure 100 in the present embodiment almost does not have cracks. In other words, test results show that, by providing a silicon carbon nitride layer, the nitride semiconductor structure 100 in the present embodiment effectively reduces the stress between the nitride semiconductor layer 140 and the silicon substrate 110 caused by thermal expansion mismatch and lattice mismatch. Therefore, the disclosure may fabricate a thicker, large-sized and higher quality nitride semiconductor structure to be applied to fields such as light-emitting diodes or power devices.

FIG. 6 is a schematic diagram of a nitride semiconductor structure according to another embodiment of the disclosure. Referring to FIG. 1A and FIG. 6, the main difference between a nitride semiconductor structure 100′ of FIG. 6 and the nitride semiconductor structure 100 of FIG. 1A is that the cubic silicon carbon nitride layer 122 in the nucleation layer 120 of FIG. 1A is replaced by a graded layer 124 comprising silicon carbide and silicon carbon nitride in a nucleation layer 120′ in the nitride semiconductor structure 100′ of FIG. 6. In the present embodiment, the thickness of the graded layer 124 comprising silicon carbide and silicon carbon nitride is about 5 nanometers to about 500 nanometers.

Due to the graded layer 124 comprising silicon carbide and silicon carbon nitride, the second nitride layer 132 including a graded AlGaN layer and the composite layer 134 including stacked silicon carbide layers and third nitride layers or stacked silicon carbon nitride layers and third nitride layers, the nitride semiconductor structure 100′ in the present embodiment reduces the stress between the nitride semiconductor layer 140 and the silicon substrate 110 resulted from thermal expansion mismatch and lattice mismatch. Thus, the probability of pits or cracks occurring on the nitride semiconductor structure 100′ is reduced.

Based on the above, the nitride semiconductor structure of the disclosure reduces the stress between the nitride semiconductor layer and the silicon substrate caused by thermal expansion mismatch and lattice mismatch by providing a silicon carbon nitride layer or a graded layer comprising silicon carbide and silicon carbon nitride, a graded AlGaN layer, stacked silicon carbide layers and third nitride layers or stacked silicon carbon nitride layers and third nitride layers, thus reducing the probability of pits or cracks occurring on the nitride semiconductor structure. Moreover, the nitride semiconductor structure of the disclosure has several advantages such as low cost, large size, high electrical conductivity and high thermal conductivity, and may be combined into optoelectronic integrated circuits with the highly developed silicon semiconductor industry, and may be applied to the field of light-emitting diodes. The light-emitting diode fabricated on the nitride semiconductor structure of the disclosure provides higher lumens/watt, enhanced color temperature, and higher color rendering index. If the process is specific for silicon wafers larger than 8 inches, the process of light-emitting diodes is compatible with the current automated semiconductor production line, and the cost is one tenth of that of sapphire substrates, effectively raising the cost-effectiveness of the light-emitting diode industry. Moreover, the nitride semiconductor structure of the disclosure can also be applied to other fields such as power devices.

Although the disclosure has been described with reference to the above embodiments, it will be apparent to one of ordinary skill in the art that modifications and variations to the described embodiments may be made without departing from the spirit and scope of the disclosure. Accordingly, the scope of the disclosure will be defined by the attached claims and not by the above detailed descriptions.

What is claimed is:

1. A nitride semiconductor structure, comprising:
a silicon substrate;
a nucleation layer disposed on the silicon substrate and comprising a cubic silicon carbon nitride (SixCyNz) layer;
a buffer layer disposed on the nucleation layer; and
a nitride semiconductor layer disposed on the buffer layer.

2. The nitride semiconductor structure of claim 1, wherein the silicon substrate comprises a surface in contact with the nucleation layer and a plurality of cavities, wherein the cavities are concave on the surface.

3. The nitride semiconductor structure of claim 1, wherein a crystal orientation of the silicon substrate is (1 1 1).

4. The nitride semiconductor structure of claim 1, wherein the parameters x, y and z satisfy the equation: x+y+z=1, and z is less than 0.3.

5. The nitride semiconductor structure of claim 1, wherein the buffer layer comprises a hexagonal first nitride layer, and the first nitride layer is in contact with the nucleation layer.

6. The nitride semiconductor structure of claim 5, wherein the first nitride layer comprises an AlN layer.

7. The nitride semiconductor structure of claim 1, wherein the buffer layer comprises a hexagonal second nitride layer and the second nitride layer is an aluminum contained nitride layer.

8. The nitride semiconductor structure of claim 7, wherein the second nitride layer comprises a graded AlGaN layer with step graded aluminum content.

9. The nitride semiconductor structure of claim 7, wherein the second nitride layer is a graded AlN/AlGaN layer or a graded AlN/AlGaN/GaN layer.

10. The nitride semiconductor structure of claim 1, wherein the buffer layer comprises a composite layer, the composite layer comprises a plurality of stacked silicon carbide layers and third nitride layers or a plurality of stacked silicon carbon nitride layers and third nitride layers, and the composite layer is in contact with the nitride semiconductor layer.

11. The nitride semiconductor structure of claim 10, wherein the third nitride layers comprise a GaN layer.

12. The nitride semiconductor structure of claim 10, wherein the silicon carbon nitride layer of the composite layer is a cubic silicon carbon nitride layer.

13. The nitride semiconductor structure of claim 1, wherein a thickness of the nitride semiconductor layer is about 0.5 micrometers to about 10 micrometers.

14. The nitride semiconductor structure of claim 1, wherein the silicon carbon nitride layer is a graded layer with graded nitrogen content.

15. The nitride semiconductor structure of claim 1, wherein the silicon carbon nitride layer comprises a graded layer comprising silicon carbide and silicon carbon nitride.
